(19) United States
(12) Patent Application Publication
(10) Pub. No.: US 2014/0150848 A1
(43) Pub. Date: Jun. 5, 2014

(54) PHOTOVOLTAIC MODULE WITH HEAT EXCHANGER

(71) Applicant: Noël Nicaise, Linars (FR)

(72) Inventor: Noël Nicaise, Linars (FR)

(21) Appl. No.: 14/236,890

(22) PCT Filed: Aug. 3, 2012
(86) PCT No.: PCT/EP2012/065212

§ 371 Date: Feb. 3, 2014

(30) Foreign Application Priority Data
Aug. 4, 2011 (FR) 1102437

(51) Int. Cl. H01L 31/0525; H01L 31/052

(52) U.S. Cl. CPC H01L 31/058; H01L 31/0521
USPC 136/248; 136/246

(57) ABSTRACT

A photovoltaic module with a heat exchanger comprises a plurality of panels comprising photovoltaic cells, a bearing structure and a heat transfer region. The bearing structure comprises a non-planar external surface forming an exposure face defining a channel with a flat central base bounded by two side walls. The bearing structure being exposed to solar radiation and bearing the photovoltaic cell panels. The heat transfer region defining a cavity having an internal surface making contact with a heat-transfer fluid flowing in the cavity. The module converts solar radiation received into electricity and transfers the heat stored and produced to a heat-transfer fluid, which after its passage through the module flows through a fluid circuit comprising a heat exchanger. The non-planar nature of the exposure face allows the area available for capturing solar radiation and the electrical power produced to be increased for photovoltaic panels of a given footprint.

### BACKGROUND OF THE INVENTION

1. Field of the Invention

The present invention relates to the field of photovoltaic panels with heat exchanger.

More specifically, the invention relates to a device comprising solar energy collection modules comprising photovoltaic cells and heat exchangers, the assembly as a whole being set up so as to optimize the performance of the photovoltaic cells and to transport the collected heat in an optimized manner.

2. Prior Art

Traditionally, the solar radiation collection modules forming the solar panels are intended for photovoltaic or thermal use. In other words, the solar panels commonly implemented generally comprise either photovoltaic cells intended to produce electricity or heat sensors designed to recover the heat produced by absorption of the solar radiation. It is clear however that the combination of the two functions in a single panel area would make it possible to multiply the possibilities for installation of these types of devices on the roofs of homes, which are limited in terms of area, in particular taking into account the orientation with respect to the sun.

In addition, when modules comprise photovoltaic cells and heat exchange means, these are not intended to transmit, by means of a heat-transfer effect, the collected heat energy to a water heater, for example, but to participate in the cooling of the photovoltaic cells in order to increase the performance thereof. In other words, the only objective of the presence of heat collection means is to facilitate the cooling of the photovoltaic cells, the heat produced during the collection of the solar radiation therefore not being recovered.

In addition, the majority of panels using assemblies formed of photovoltaic cells and heat exchangers are generally positioned in planar layers. For example, a planar module formed of photovoltaic cells forms one layer of the device and is superimposed on a tubular network which circulates in a rectangular parallelepiped beneath the plane of photovoltaic cells. Planar mixed structures comprising a plane of photovoltaic cells beneath which a cooling device, which collects the heat energy dissipated by the cells, is placed in contact with the aforesaid plane, are thus obtained; this device may consist of a circulation of gaseous or liquid cooling fluid.

Patent FR 2 924 664 (PROISY e.) for example describes a device having a set of photovoltaic cells on a first face intended to be exposed to the solar radiation and a heat exchanger on a second face intended for the passage of a cooling fluid and which is formed in particular of pulsed-air passage means.

Solar modules that can be classified as hybrid solar modules start to appear in the prior art and in particular have begun to be commercialized. In the literature, some patents describe devices that attempt to provide a solution to this problem.

Patent FR. 2 779 275 (GARABEDIAN G.) describes a device formed of modules comprising photovoltaic cells covering the heat exchangers transporting the heat-transfer fluid. In this case, the device again is a plate of photovoltaic cells covering a sleeve containing a heat-transfer fluid and arranged in a coiled manner.

One of the devices sold on the market follows this approach by proposing modules composed of photovoltaic cells, beneath the face of which an aluminum plate covering a heat exchanger, with heat-transfer fluid, is located. The assembly can satisfy the needs in terms of electrical energy and in terms of heating liquid.

The same is true for the devices described in patents WO 01/99203 (LUTZ P.), WO 2007/129985 (TOH P. S.), WO 2008/044250 (AGUGLIA J.) and also WO 2008/125264 (VINCENZ M,).

Patent EP 1693 901 (BIUCCHI S., MANTONVANI M.) describes a hybrid device formed of photovoltaic cells contained in a closed circular chamber, in the center of which a conical light reflector device is arranged and is intended to trap the greatest quantity possible of photons in order to reflect them onto the cells that cover the walls of the chamber. A heat exchanger may also be arranged over part of the walls of the chamber, but is not used to cool the photovoltaic cells or to optimize the surface of heat-transfer liquid in contact with the solar rays.

However, although these aforesaid devices respond to the problem of providing a hybrid solution, they do not make it possible to obtain an exchange area that is optimized, both for the photovoltaic cells and for the coils transporting the heat-transfer fluids. In other words, the existing hybrid systems are far from being optimized, in terms of electricity production or in terms of utilization of the heat produced and utilized.

The majority of solar sensors currently sold on the market therefore comprise, for two square meters of area, heat-transfer coils measuring twelve millimeters in diameter for a length of twenty meters. On average, the useful heat exchange area between the sun and the heat-transfer liquid is therefore approximately seventy-five square decimeters. It is quite conceivable to increase this area in contact with the sun at least by a half so as to increase the efficiency of such devices, by reducing the total area or by increasing the coiled area in contact with the heat of the sun, depending on a new arrangement of the elements with respect to one another. In other words, it is possible to optimize the relative arrangements of the different elements, photovoltaic sensors and heat sensors, so as to increase the overall performance for a given sensor area, in terms of electricity production or in terms of use of the heat produced.

The prior art therefore does not satisfactorily solve the problem of optimizing modules intended to produce electrical energy and heat from natural sunlight.

### SUMMARY OF THE INVENTION

The object of the present invention is to overcome these disadvantages by proposing a device comprising solar energy collection modules comprising photovoltaic cells and heat exchangers, or more generally heat exchange means, the assembly being set up so as to optimize the performance of the photovoltaic cells and to transport the produced heat in an optimized manner.

To this end, the invention relates to a photovoltaic module with a heat exchanger, comprising a plurality of panels formed of photovoltaic cells, characterized in that it further comprises a bearing structure, itself comprising a non-planar external surface forming an exposure face defining a channel with a flat central base delimited by two side walls, said structure being intended to be exposed to solar radiation and bearing the photovoltaic cell panels, and a heat transfer region having a surface intended to make contact with a heat-transfer fluid flowing on its surface.

The heat energy stored and produced by the panels of photovoltaic cells is thus advantageously transferred by the bearing structure to the heat-transfer fluid, said structure serving as a heat pipe.

In accordance with a first embodiment of the device according to the invention, the bearing structure is formed of pipes which are flattened over substantially their entire length, are arranged along the length of the channel, and in which a heat-transfer fluid circulates, said pipes forming a means for transporting said heat-transfer fluid within the structure, and forming the central base and also the walls of the channel, the panels of photovoltaic cells being fixed to the walls of said pipes exposed to the solar radiation and forming the exposure face of the structure, the inner walls of the pipes forming the heat transfer region.

The central element and the side element forming said means for transporting the heat-transfer fluid advantageously constitute means for cooling said panels of photovoltaic cells.

In accordance with a feature of this embodiment, the pipes forming the bearing structure are arranged so as to form a channel that is substantially U-shaped in cross section.

In accordance with a further feature, the device according to the invention comprises an inlet element or inlet transport means for the heat-transfer fluid and an outlet element or outlet transport means for said fluid, said pipes conveying the heat-transfer fluid from the inlet heat-transfer fluid transport means to the outlet heat-transfer fluid transport means.

In accordance with a further feature, said heat-transfer fluid inlet means and outlet means are designed so as to be interconnectable via a heat exchanger cooling the heat-transfer fluid once said fluid has passed through the bearing structure. In other words, in accordance with a further feature, the heat-transfer fluid inlet and outlet elements are designed so as to be interconnectable externally via a heat exchanger that cools the heat-transfer fluid once said fluid has passed through the device.

In accordance with a second embodiment of the device according to the invention, the bearing structure is formed by a block of material that is a good thermal conductor comprising a non-planar exposure face forming a channel, over the walls of which the panels of photovoltaic cells are fixed, and comprising a heat transfer face forming an open cavity, and by a plate made of a conductive material forming a cover for said cavity.

Said cavity comprises a plurality of longitudinal furrows, the ends of said furrows opening onto two transverse furrows. Said heat transfer face is designed in such a way that, when the formed cavity is covered by the plate forming a cover, the longitudinal and transverse furrows form separate pipes in which the heat-transfer fluid circulates, the longitudinal pipes communicating with the two transverse pipes via their ends. The cover is equipped with two diametrically opposed openings arranged so as to open out at opposite ends of the two pipes formed by the transverse furrows.

In accordance with a feature of this embodiment, the transverse furrows are designed so as to form a distribution channeling for distributing the heat-transfer fluid at the entry to the longitudinal pipes, and a collector for collecting the heat-transfer fluid at the exit from the longitudinal pipes. Said transverse pipes each have a section which varies continuously over their length, the openings for the entry and exit of the heat-transfer fluid being arranged so as to open onto the larger ends of said pipes.

In accordance with a further feature, the cover, at each of the openings, comprises means for fixing a connection element, enabling the device to be connected to an external system for circulating and conditioning the heat-transfer fluid.

In accordance with an advantageous embodiment, each module comprises a means for refracting and reflecting solar rays, said means being housed in the space delimited by the walls of the exposure face which bear the panels of photovoltaic cells.

In accordance with a feature of this embodiment, a passive optical device is housed in the inner cavity of the channel, said device comprising two semi-transparent sheets arranged so as to form the adjacent faces of a triangular prism, the edge joining these two faces being directed toward the outside of the channel; said semi-reflective sheets being dimensioned so as to reflect some of the radiation directly received via the exposure face onto one of the walls of the channel.

The invention also relates to a photovoltaic panel with a heat exchanger, comprising a plurality of photovoltaic modules with heat exchangers according to the invention, said photovoltaic modules being juxtaposed with respect to one another, the bearing structures of the different modules being mechanically joined so as to form a common bearing structure comprising an exposure face, said exposure face forming a plurality of channels, over the walls of which the panels of photovoltaic cells constituting the different modules are mounted, and comprising a heat transfer surface covering all of the modules, the single bearing structure making it possible to optimize the space occupied by the panel thus formed.

In accordance with a feature, said panel comprises a system for circulating the heat-transfer fluid and for conditioning the heat-transfer fluid, this system itself comprising a heat exchanger making it possible to cool the heat-transfer fluid that has passed through the cavity forming the heat exchange region of the panel before it is returned to the panel.

In accordance with a further feature, said panel further comprises, fixed to the outermost side walls of the bearing structure, two additional photovoltaic panels and two additional reflectors, one of said reflectors being fixed to each of the side edges of the bearing structure, these additional reflectors being arranged so as to reflect the solar radiation onto the panel with which it is associated.

The invention also relates to an overall energy production system, characterized in that it comprises a plurality of photovoltaic panels according to the invention and means for utilizing the heat produced in the heat exchanger in order to heat a body of water.

### BRIEF DESCRIPTION OF THE DRAWINGS

Further features and advantages of the invention will be better understood upon reading the following description of an embodiment provided with reference to the accompanying figures, in which:

FIG. 1 shows a cross-sectional view of two solar energy collection modules in accordance with a first embodiment of the invention;

FIG. 2 shows a partial longitudinal sectional view, in a plane parallel to the plane of installation of the module, of one of the ends of two solar energy collection modules in accordance with the first embodiment, these modules being connected to the transport means of “cold” heat-transfer fluid;

FIG. 3 shows a cross-sectional view of a module in accordance with the first embodiment surrounded by two side cooling means and by a central cooling means;

FIG. 4 shows a longitudinal section from above of a photovoltaic panel with a heat exchanger in accordance with the first embodiment of the invention;

FIG. 5 shows a cross-sectional view of a module in accordance with a variant of the first embodiment of the invention surrounded by two side cooling means and by a central cooling means;

FIG. 6 shows a view of an entire bearing structure of the device according to the invention in a second embodiment, the structure being common to two modules;

FIG. 7 shows a cross-sectional view of the device according to the invention in this second embodiment;

FIG. 8 shows a view from below of the heat exchange face of the bearing structure of the device according to the invention in a second embodiment;

FIG. 9 shows a view of the external face of the element forming the cover of the heat exchange region of the bearing structure of the device according to the invention in a second embodiment; and

FIG. 10 shows a schematic front view of a photovoltaic panel with a heat exchanger according to the invention.

### DETAILED DESCRIPTION OF PREFERRED EMBODIMENTS

To optimize the performance of a conventional modular hybrid solar energy collection device, it is thus necessary to obtain an exchange area larger than the area of received sunshine in the plane in which the device stands. To this end, the invention has the effect of making it possible, knowing the area on the ground available for implanting solar sensors, to arrange an exposed area larger than the area on the ground, by taking advantage of the volume effect from which the exposure area of the device modules according to the invention benefits, this area being non-planar on principle.

However, if the amount of light absorbed into the material of the photovoltaic cells in the form of photons, in other words the amount of energy absorbed by the photovoltaic cells under the action of the solar radiation, increases, the temperature of the cells also increases. In order to be effective, the photovoltaic cells must be kept at a certain temperature and must not exceed a maximum limit temperature. This is one of the reasons why the device according to the invention comprises a thermodynamic cooling means for cooling the photovoltaic cells, of which the performance in terms of electricity production is thus improved.

To this end, the device according to the invention consists of a photovoltaic module comprising a bearing structure having a non-planar exposure face for exposure to the solar rays, said face forming a base wall delimited by side walls. This area defines a channel, that is to say a groove, of which the planar base wall represents the bottom. In accordance with the invention, the side walls are inclined to a greater or lesser extent, the angle of inclination with respect to the plane defined by the base wall as well as the width of the base wall and the height of the side walls being dependent on the desired illumination.

In accordance with the invention, each of the walls, that is to say the base wall as well as the side walls, is covered by a panel of photovoltaic cells.

In addition, the bearing structure of the photovoltaic module has a heat exchange face defining a heat transfer region in which a heat-transfer fluid circulates. The heat transfer region of the structure is designed so as to maximize the contact and heat exchange with the heat-transfer fluid.

In accordance with the invention, the heat transfer region is designed and dimensioned in such a way that, as the heat-transfer fluid circulates within said region, it remains in contact with the heat exchange face of the structure for a period of time sufficiently long for it to sufficiently recover the heat transmitted via the bearing structure, in order for the photovoltaic cells to remain below their maximum operating temperature, taking into account the expected sunshine, and preferably in the vicinity of the optimal temperature.

The heat transfer region further comprises an entry path for the fluid, said path being terminated by an entry opening, and an exit path for the fluid, said path being terminated by an exit opening. These two paths are dimensioned and arranged within the bearing structure in such a way that, between the entry and the exit, the heat-transfer fluid travels through the entire heat exchange region with a preferably constant flow rate.

The entry and exit openings are additionally provided with terminations making it possible to connect the exit opening to the entry opening by means of an external heat exchanger, in order to remove and possibly recover the heat transported by the heat-transfer fluid once it has passed through the heat exchange region of the bearing structure.

In accordance with the invention, the bearing structure that carries out the heat transfer is made of a material that is a good thermal conductor, for example brass, copper or aluminum.

The thermal contact between the bearing structure and the solar energy collection means, that is to say the panels of photovoltaic cells, may additionally, depending on the embodiment, be strengthened by arranging an interface layer made of material that is a good thermal conductor or by arranging a thermally conductive paste between the two elements.

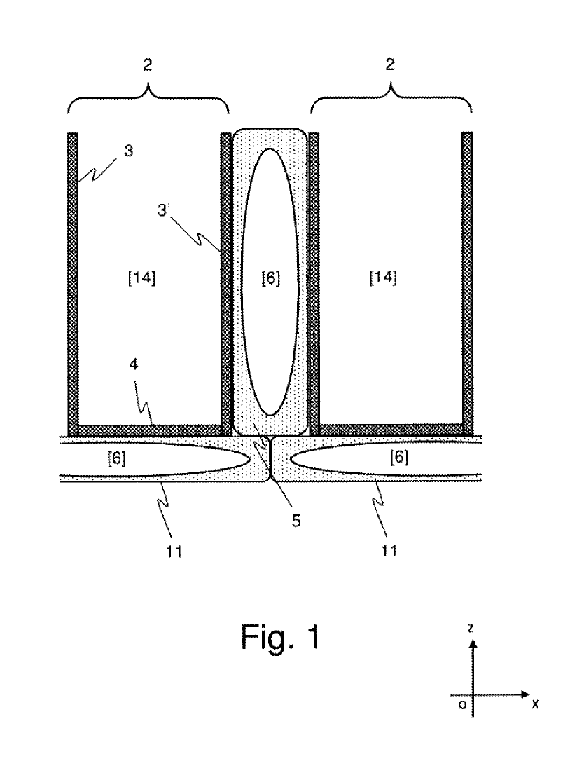

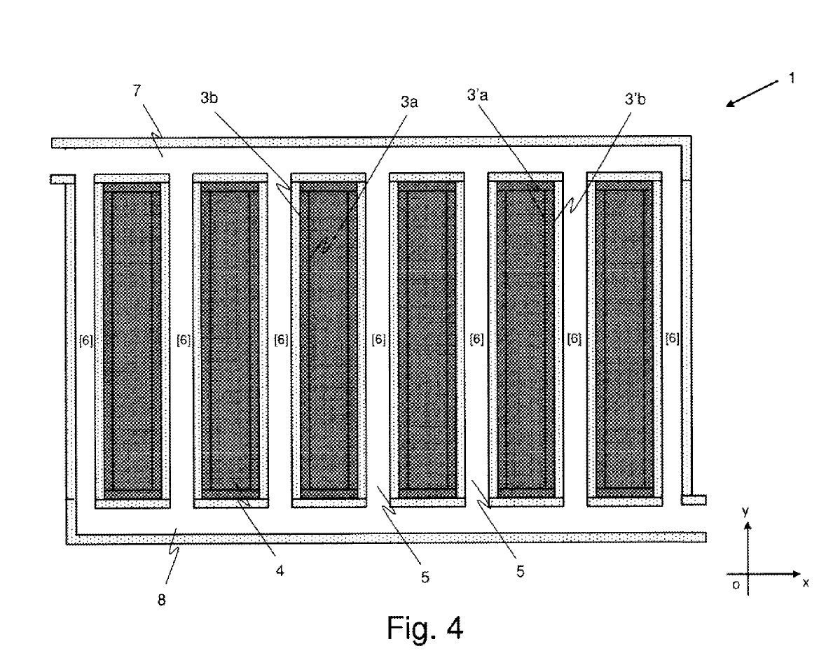

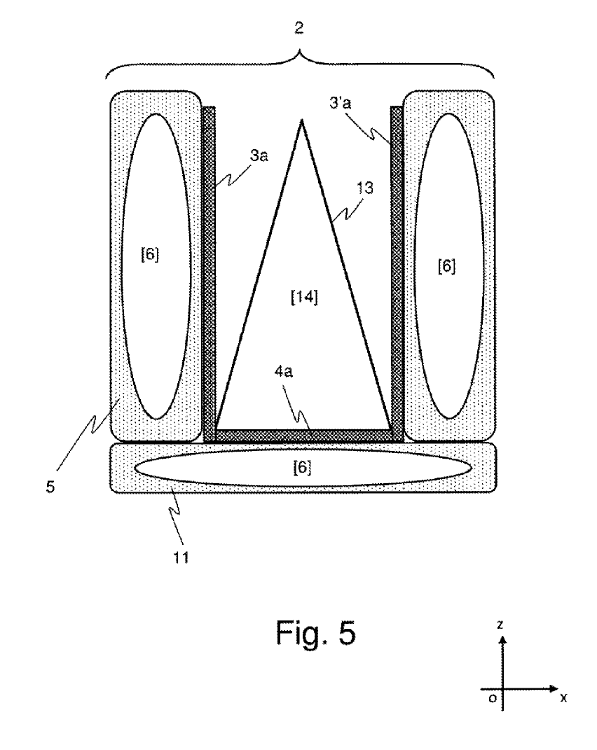

FIGS. 1 to 5, by way of example, show a first embodiment of the invention.

In accordance with this first embodiment, which for example is considered to be non-limiting, a photovoltaic panel with heat exchanger comprises, as illustrated in FIG. 1, a set of photovoltaic modules 2 according to the invention, comprising photovoltaic conversion means 3, 3′ and 4, and heat conversion means 5, 11, or more specifically heat exchange means. The heat exchange means 5, 11 are formed of means for circulating a heat-transfer fluid along the heat exchange face of each module. These means, for each module, have a central element 11 in contact with the base 4 of each photovoltaic conversion means, and side element 5 in contact with the side walls 3 of each of these means. They thus form a support for the photovoltaic conversion means 3, 3′ and 4.

The photovoltaic conversion means 3, 3′ and 4, preferably photovoltaic cells, when they are sunlit, dissipate heat energy that is recovered by the heat conversion means 5, 11, which are tasked with collecting and transferring the heat produced by the photovoltaic conversion means 3, 3′ and 4.

In this embodiment, each photovoltaic module comprises three longitudinal and planar parts. These three parts are joined together on their longest sides. The assembly forms a “U”-shaped channel closed at each end and comprising a base face or central part 4a and two side faces or parts 3a and 3a′. The central part 4 is joined along each of its lengths to a side part 3 and 3′. The assembly thus formed has a concave face 3a, 3a′ and 4a, so called exposure face, bounding the channel 14, intended to be lit by the solar radiation, and a convex face 3b, 3b′ and 4b forming an external face intended for the transfer of heat.

The planar base formed by the central part of the “U” is covered on a face 4a by a photovoltaic film, intended to receive the solar radiation in order to convert it into electrical energy. The photovoltaic film is preferably formed of a set of photovoltaic cells covering the surface of the base 4a.

As a continuation of this photovoltaic film, the two side parts or walls 3 and 3′ are also covered with a photovoltaic film over the entire area of the face arranged on the same side 3a, 3a′ as the photovoltaic face 4a of the central part. The inner part of the “U”, in other words of the channel 14, thus forms a solar radiation trap devoted to converting said solar energy into electricity. The surface for collecting the solar radiation is thus increased with respect to that obtained with a planar surface that would be the equivalent of the surface occupied by the central part 4 of the “U”.

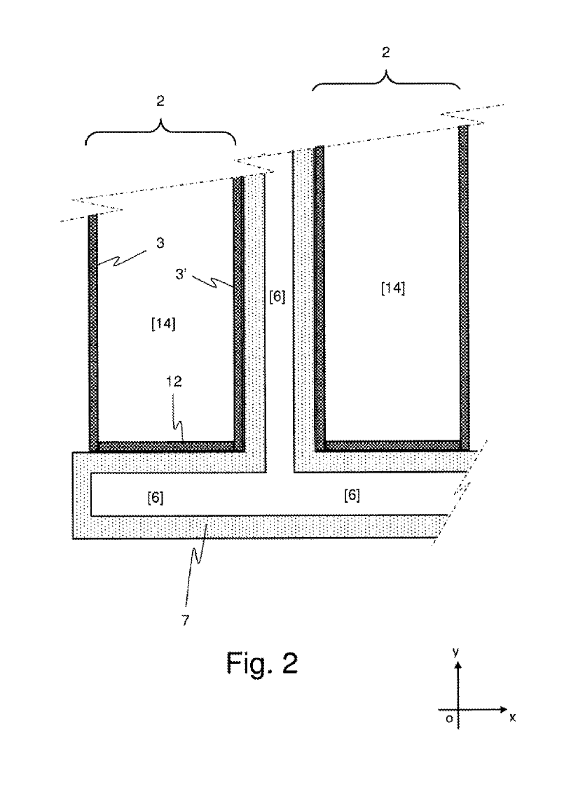

In accordance with the invention, as illustrated in FIG. 2, each end of the “U”s formed by the modules 2 is closed by a wall, of which the inner face is covered by a panel of photovoltaic cells 12.

In this embodiment, the modules 2 forming a photovoltaic panel with heat exchanger, for example six modules, and the side 5 and central 11 heat conversion means, form the “U”-shaped body of each of the modules 2. In other words, the heat transfer means, which carry the photovoltaic cells on their surface, constitute the bearing structure of each photovoltaic module.

For a six-module panel, six heat conversion means, that is to say six central elements 11 forming the base of the “U”s, and seven heat conversion means, that is to say seven side elements 5 supporting the sides of each “U”, are thus used, for example.

In accordance with this first embodiment, the heat conversion means 5, 11 are hollow flattened copper pipes, inside which a heat-transfer fluid 6 circulates. These pipes thus also form the heat exchange region of the bearing structure, a region which here thus occupies the entire volume of the bearing structure formed by the pipes themselves.

Said heat conversion means, in which the heat-transfer fluid circulates, are formed for example by flattened copper tubes measuring from thirty to thirty-two millimeters in diameter and arranged longitudinally, as illustrated in FIG. 1 in particular.

Once flattened, the tubes have a width of approximately eight centimeters, which corresponds substantially to the height of the passage of the heat-transfer fluid. This passage is then approximately two millimeters thick. It is perfectly conceivable to use pipes having a different height as long as they are flat and can perform two functions, that of transporting heat-transfer fluid and that of forming the body.

Since the length of each of the tubes 5, 11 is fixed, the photovoltaic panel formed has a given basic area. By contrast, the thermal area that can be utilized is much greater.

For example, for tubes having a length of approximately thirty-three centimeters, the area occupied by the panel is approximately equal to thirty-three centimeters by thirty-three centimeters, or approximately eleven square decimeters. By contrast, the area that can be utilized is approximately forty-eight square decimeters.

Such a panel allows the assembly of one hundred and twenty 0.5 V solar cells for 400 mA, measuring 76 mm by 46 mm.

The photovoltaic cells are adhesively bonded to each of the flattened pipe faces constituting the body. The adhesive used is preferably an electrically insulating adhesive.

In this first embodiment, as illustrated in FIGS. 1 to 5, the photovoltaic modules form U-shaped cavities such that the inner side walls 3a and 3a′ of the modules are substantially perpendicular to the base 4a. Taking into account the reflective nature of the surface of the photovoltaic cells used, these modules perform both a function of absorbing and converting photons into electricity and also a function of reflecting these photons toward the central part 4a, thus making it possible to concentrate a greater quantity of photons in the module for converting the light radiation into electrical energy (photovoltaic module).

In a preferred form of this embodiment, the width of each side wall 3 and 3′, in other words the height of the walls of the channel, is identical and one and a half times larger than the width of the central part 4. The area of each wall is thus equal to one and a half times the area of the central part. As a result, the total area of the panels of photovoltaic cells is 4 times greater than the area necessary to position the entire module formed by these panels of photovoltaic cells. The exchange area is thus larger than the area of received sunlight. In other words, the area for collecting the solar radiation is substantially larger than the area occupied on the ground by a photovoltaic module 2 according to the invention. For a square meter of received sunlight, that is to say the area taken up on the ground by a planar photovoltaic panel, the device makes it possible to achieve four square meters of exchange area.

The heat-transfer fluid transport pipes are connected from one side of the panel by one of their ends to a cold heat-transfer fluid transport means 7, which feeds heat-transfer fluid to the different pipes 6, whereas the heat-transfer fluid transport pipes are connected by their other end to the heated heat-transfer fluid transport means 8, or collector, which recovers the heat-transfer fluid once it has passed through the heat exchange region of the device.

Said fluid transport means are, for example, collectors formed of copper pipes from thirty to thirty two millimeters in diameter and soldered to a hollow copper element ensuring the tightness and the transport of the heat-transfer fluid to the entries and exits of each of the means 5, 11 for transporting said fluid, in other words the flattened pipes in which the heat-transfer fluid circulates within the device.

In accordance with a specific form of this embodiment, means for reflecting and refracting the sun rays are positioned within each of the “U”s of the photovoltaic modules 2. This is so as to capture the greatest quantity possible of the collected solar rays convertible by the photovoltaic cells.

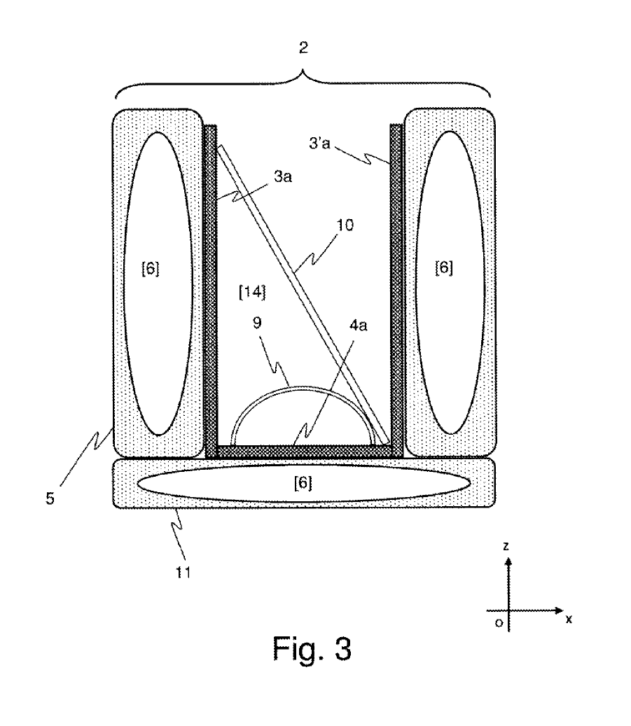

In a first variant of this embodiment, illustrated by FIG. 3, a reflector 9 made of rigid plastic or made of glass or any other material having the known properties for reflecting and/or refracting the sun and being substantially transparent and convex, is arranged at the base of each “U”. Alternatively, in accordance with a further variant illustrated in FIG. 3, a planar semi-reflective sheet 10 is positioned at an angle between two opposite lengths of the same diagonal of the rectangular parallelepiped formed by the “U”. In yet a further variant (not illustrated in the figures), the reflector may consist of two rectangular plates joined together along one of their lengths and forming an inverted V, 13, within the “U”.

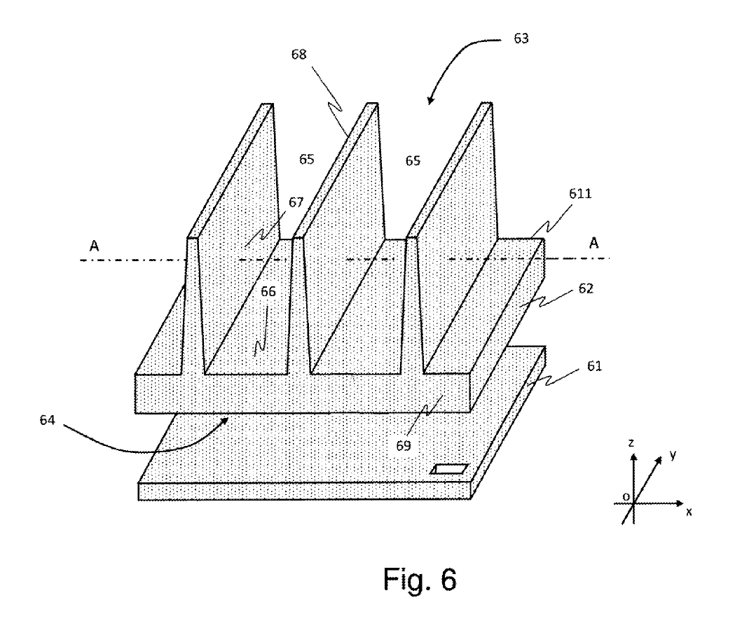

FIGS. 6 to 10, also by way of example, show a second embodiment of the invention.

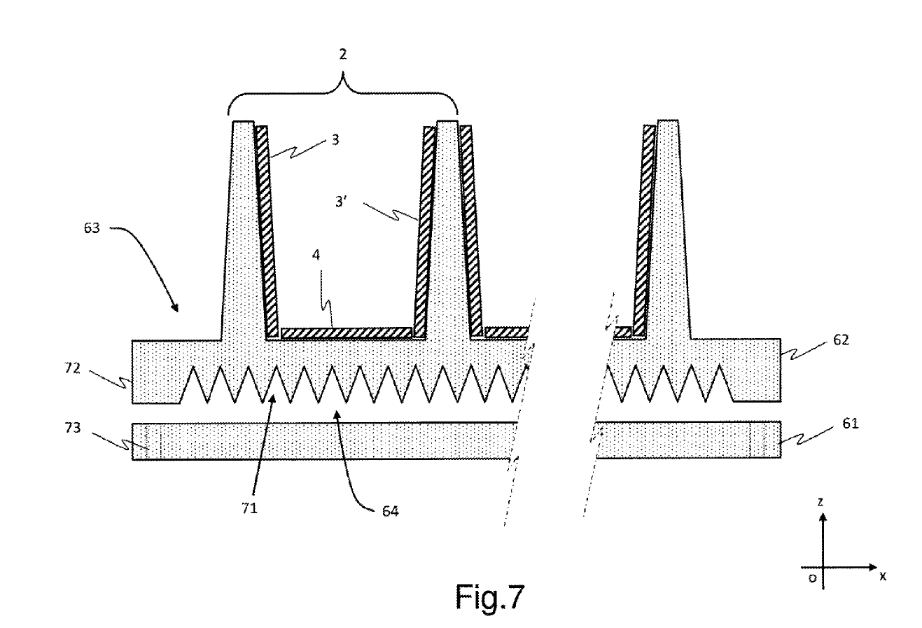

In accordance with this second embodiment, also provided by way of non-limiting example, each photovoltaic panel with heat exchanger comprises, as illustrated in FIGS. 6 and 7, a set of modules 2 comprising photovoltaic conversion means 3, 3′ and 4 and a bearing structure 62 comprising a heat transfer region, making it possible to remove the heat produced by the photovoltaic conversion means. In accordance with this embodiment, the heat transfer means comprise two elements 61 and 62, the element 62 forming the bearing structure of the photovoltaic conversion means 3, 3′ and 4.

In this embodiment, the bearing structure 62 is preferably, but not necessarily, common to a set of photovoltaic modules with heat exchanger according to the invention. However, a common bearing structure advantageously makes it possible to juxtapose a set of devices over a minimal area.

The structure 62 comprises an exposure face 63, intended to receive the solar radiation, and a heat exchange face 64, which forms the heat transfer region.

The exposure face 63 is formed by a non-planar surface (i.e. not arranged in one plane) forming, depending on whether a structure comprising one or more devices according to the invention is provided, one or more channels 65, each channel being formed by a planar base 66 and oblique walls 67 and 68, on which the photovoltaic cells constituting the photovoltaic conversion means 3, 3′ and 4 of a module, or photovoltaic panels, are mounted.

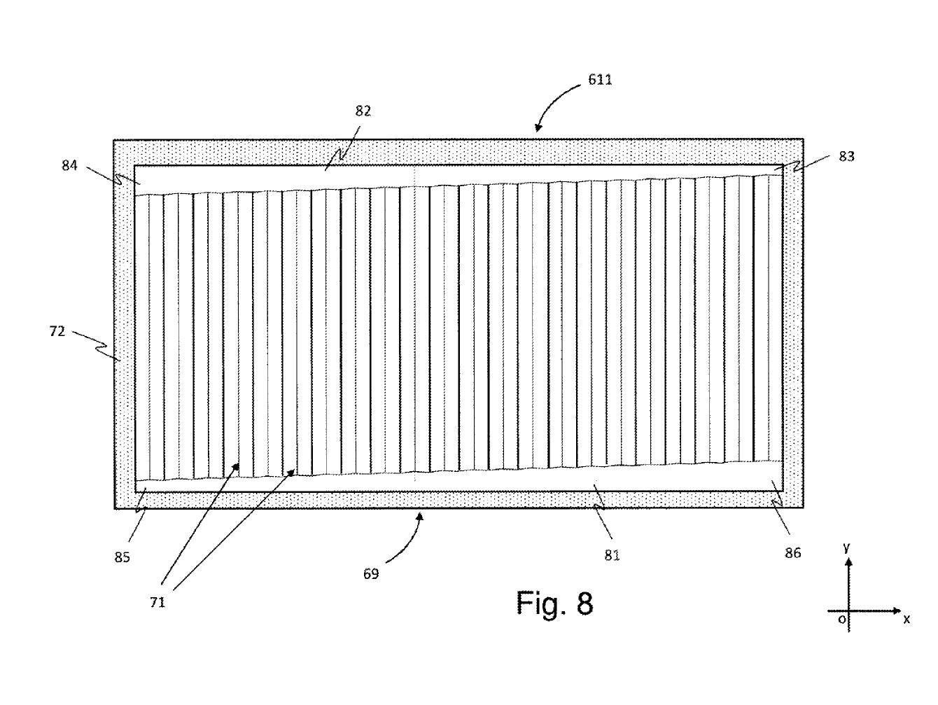

The heat exchange face 64 is a surface comprising a set of longitudinal furrows along the axis oy shown in FIG. 6, said furrows being formed in the thickness of the material substantially covering the entire central part of the heat exchange face 64, the periphery of the exchange face forming a flat edge 72, as illustrated in FIG. 8. These longitudinal furrows, of defined diameter, form open ducts 71.

The heat exchange face also has two transverse furrows 81 and 82, which are arranged at the two ends 69 and 611 corresponding to the front and rear faces of the structure and which constitute two ducts onto which the longitudinal furrows 71 lead.

These transverse furrows 81 and 82, also formed in the thickness of the material, have a section that varies continuously over their length, and therefore have two ends having different sections. These two furrows are preferably substantially identically shaped and each have an outer edge substantially parallel to the front or rear wall of the structure 62, as illustrated in FIG. 8.

The two transverse furrows 81 and 82 are also arranged such that the narrowest end 83 of the transverse furrow 81 is positioned opposite the widest end 86 of the furrow 82.

In accordance with the invention, the furrows 71, 81 and 82 may have a section of variable shape, such as a triangular section, as illustrated by FIG. 7, or may have a circular or rectangular section.

Due to reasons of practicality, the bearing structure 62 is made of a material selected for its heat conduction qualities, for example a metal material such as copper or aluminum.

The bearing structure 62 is associated with a planar element 61 forming a cover that is intended to be assembled on the bearing structure against the heat exchange face 64 so as to close the longitudinal furrows 71 and transverse furrows 81 and 82, and to form a tight hollow structure formed of a plurality of separate ducts, of which the ends open into the two cavities formed by the furrows 81 and 82, which are also closed by the element 61.

The purpose of these ducts is to allow the heat-transfer fluid to circulate within the heat exchange region such that said fluid comes into contact with the surface 64. To this end, the dimensions of the longitudinal furrows are preferably defined so as to maximize the heat exchange area.

For reasons of practicality, the element 61 is preferably made of the same material as the bearing structure 62.

It should be noted in addition that the longitudinal furrows 71 and transverse furrows 81 and 82 are produced such that the fixing of the element 61 on the bearing structure 62 brings the inner face of the element 61 into contact with the edges of each of the furrows, such that each furrow thus covered forms a duct separate from the other ducts formed by the other furrows.

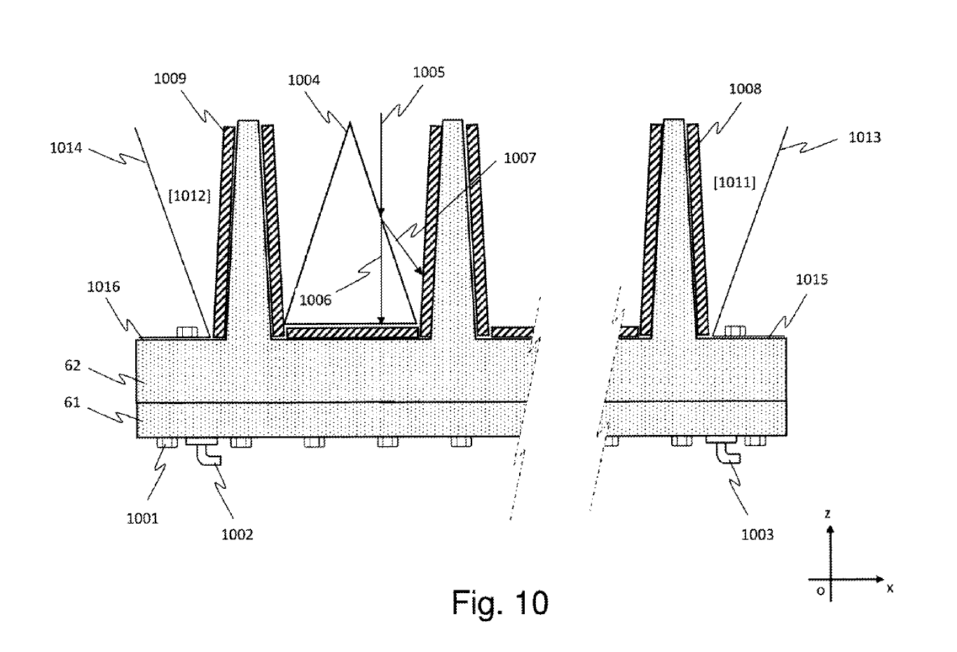

In accordance with an advantageous embodiment, the cover 61 is fixed to the heat exchange face 64 by screws 101, as illustrated by FIG. 10. To this end, the cover thus comprises holes 73, through which the screws pass in order to become engaged in the threads 74 provided for this purpose on the structure 62. To increase the tightness of the assembly, it is additionally possible to arrange a seal between these two parts. Alternatively, this assembly can be produced, however, by any known tight assembly method, for example by soldering or brazing the cover to the face 64.

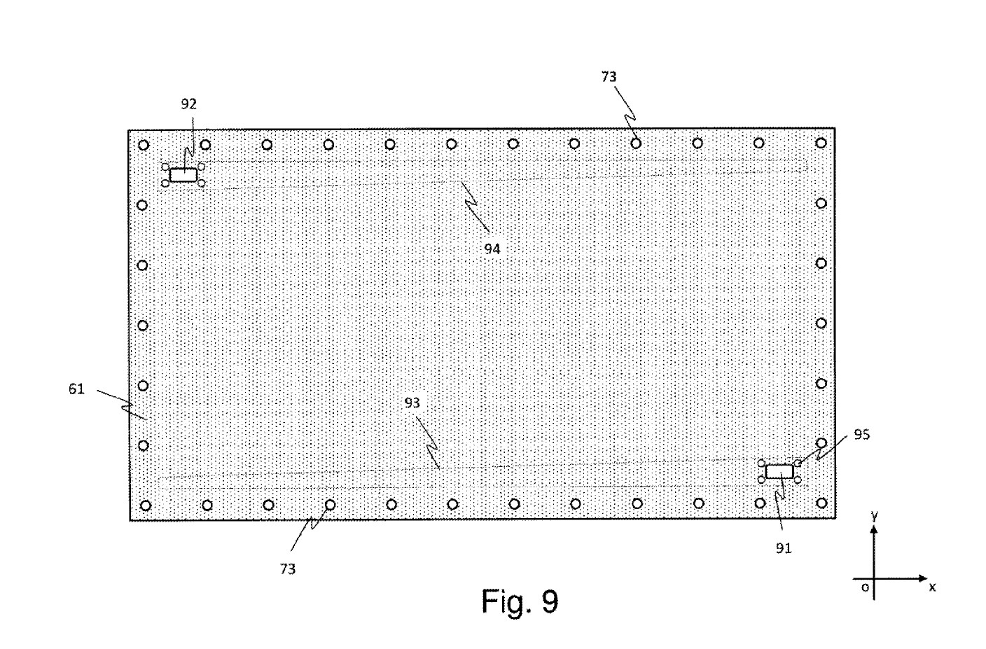

In this second embodiment, the cover 61 comprises, as illustrated in FIG. 9, two openings 91 and 92 which pass through the cover. These two openings are positioned so as to open out into one or other of the cavities formed by the transverse furrows 81 and 82 when the cover is mounted on the bearing structure 62, moreover said openings are positioned at the wider end of the cavity in question. These furrows are shown virtually by the dotted lines 93 and 94 in FIG. 9.

These openings are preferably surrounded by fixing points, for example threaded holes 95, arranged so as to enable a nozzle, or more generally an interface, to be fixed, for example with the aid of a flange, thus making it possible to connect a pipe to the device.

The photovoltaic modules are formed of panels, in turn formed of photovoltaic cells. Each module is thus housed in a channel 65, the panels forming this module being arranged on the base 66 and the walls 67 and 68 of the corresponding channel. These panels are fixed to the walls 66, 67 and 68 by any means suitable, ensuring good thermal contact with these walls and, consequently, with the entire bearing structure 62. The heat dissipated by the photovoltaic panels can thus be transmitted to the bearing structure and, subsequently, to the heat exchange region.

As in the first embodiment described, the device according to the invention thus comprises a bearing structure that also constitutes the means for transferring heat energy to a heat-transfer fluid circulating within this structure through pipes, the photovoltaic modules being fixed directly to said bearing structure.

As regards its function, the device according to the invention is designed, in this second embodiment, as in the first embodiment, to be combined with a fluid circulation circuit which allows a heat-transfer fluid, preferably a cooled fluid, to circulate through the pipes formed in the bearing structure.

In the case of the second embodiment, the heat-transfer fluid more specifically circulates in the hollow structure delimited by the face 64 of the bearing structure 62 and by the inner face of the cover 61. To this end, the openings 91 and 92 are equipped with means, making it possible to connect pipes to the device, that is to say connection nozzles 1002 and 1003 as illustrated in FIG. 10 for example.

The heat-transfer fluid is thus introduced into the hollow structure via the entry opening 91 and discharges into the distribution channeling formed by the transverse furrow 81, where it is distributed among the pipes formed by the longitudinal furrows 71. After passing through the different longitudinal pipes, the fluid discharges into the collector formed by the channeling, which is formed by the transverse furrow 82, and emerges from the device via the exit opening 92 and is introduced back into the circulation circuit.

It should be noted that the specific structure of the furrows 81 and 82 advantageously makes it possible to form a distribution channeling and a collector which ensure that the fluid is distributed among the different longitudinal pipes with a substantially constant pressure.

As it passes through the pipes forming the hollow structure, the heat-transfer fluid enters largely into contact with the heat transfer face 64 of the bearing structure 62, such that it produces a transfer of heat between the bearing structure and the heat-transfer fluid, the former transmitting to the latter the heat energy transmitted to it via the photovoltaic panels.

This exchange ensures the cooling of the bearing structure and consequently that of the photovoltaic panels. The temperature of the heat-transfer liquid at the exit is consequently higher than its temperature at the entry.

The heat-transfer fluid circulation circuit is generally designed to ensure the injection into the device of a heat-transfer fluid, of which the temperature is lower than the temperature of the device during operation. For example, said circuit may consist of a set of distribution pipes connected to the entry of the device according to the invention and a set of collection pipes connected to the exit of the same device, these sets of pipes being mounted respectively at the exit and entry of a cooling system.

A closed fluid circulation circuit is thus formed, in which the heat-transfer fluid cooled by the cooling system is sent into the device, whereas the heat-transfer fluid heated by passing through the device is sent back to the cooling system.

In this second embodiment, similarly to the first embodiment, the device according to the invention comprises means, making it possible to increase the lighting of the photovoltaic cells forming the panels arranged on the side walls of the exposure surface. These means are formed here for each module of a hollow semi-reflective element 1004 of triangular section, of which the length is substantially equal to that of the channel 65, over the walls of which the panels 3, 3′ and 4 are arranged. As illustrated in FIG. 10, the direct light rays perpendicularly lighting the exposure surface of the device, represented by the arrow 1005, are thus transmitted in part to the photovoltaic panel placed on the base 66 of the channel 65, as indicated by the arrow 1006, and are partially reflected onto the panels placed on the side walls 67 and 68, as indicated by the arrow 1007. More generally, depending on the incidence of the solar illumination, a panel fixed to a given wall advantageously receives both direct radiation at a given incidence and radiation reflected by one or other of the walls of the element 1004. The proportions of direct illumination and illumination by reflection depend in principle on the reflective index of the material, geometry of the device and the angle of incidence of the solar illumination onto the wall in question.

In order to further increase the electrical power produced, the device according to the invention, in a variant of the second embodiment, may advantageously comprise two additional photovoltaic panels 1008 and 1009 on the outermost side walls of the bearing structure 62, that is to say walls that do not define a channel. In such a configuration, an additional reflector 1013, 1014 is fixed to each of the side edges 1015 and 1016 of the bearing structure. These additional reflectors are arranged, as illustrated in FIG. 10, so as to reflect the solar radiation toward the panel 1008, 1009 with which it is associated.

It should be noted that, with regard to use and whatever the considered embodiment, the cooling system of the heat-transfer fluid circulation circuit may consist, as already mentioned above, of a simple cooling system. The device thus simply plays the role of a photovoltaic generator. Alternatively however, it may consist of a heat exchange system integrated for example in a hot water production system. Coupled to such a system, the device according to the invention thus advantageously plays the role both of an electrical energy generator and of a solar hot water production system, such that the heat energy dissipated by the photovoltaic panels is not discharged purely as waste heat. The energy yield of the assembly is thus improved considerably. In addition, the solar hot water production system may be connected to a water tank used conventionally in solar water heaters, whereas the photovoltaic cells may be connected to a means for accumulating the electrical energy. It is thus advantageously possible to provide a complete system that produces electrical energy and heat energy and stores these energies.

As demonstrated by the above description, the photovoltaic module with heat exchanger according to the invention is a device that may advantageously be produced in unit form comprising a bearing structure having an exposure face forming a channel with a base and side walls able to receive photovoltaic panels, these being fixed to the base and to the side walls, and comprising a heat transfer region in which a heat-transfer fluid circulates. The bearing structure thus serves advantageously both as a support for the photovoltaic conversion means and as a heat exchange structure.

The module according to the invention is generally intended however to be combined with other identical modules so as to form larger structures, or what are known as solar panels, by simple juxtaposition of modules. In this case however, in order to optimize the bulk of the assembly, the modules forming the structure are formed integrally. The bearing structure is thus a continuous structure of which the exposure face has a juxtaposition of channels 65, as illustrated by FIG. 1 or FIG. 10 for example.

Any minor changes obvious to a person skilled in the art to the use or fabrication of the device according to the invention that forms the basis of the patent, without modifying the original provisions, are merely simple technical equivalents likewise falling within the scope of the present invention.

1-14. (canceled)

15. A photovoltaic module with a heat exchanger, comprising:
a plurality of panels formed of photovoltaic cells;
a bearing structure comprising a non-planar external surface forming an exposure face defining a channel with a flat central base delimited by two side walls, the bearing structure being exposed to solar radiation and bearing the photovoltaic cell panels; and
a heat transfer region having a surface in contact with a heat-transfer fluid flowing on its surface.

16. The photovoltaic module of claim 15, wherein the bearing structure is formed of pipes which are flattened over substantially their entire length and are arranged along a length of the channel; wherein the heat-transfer fluid circulates within the pipes; wherein the pipes transports the heat-transfer fluid within the bearing structure, and the pipes form the flat central base and the side walls of the channel; wherein the panels of photovoltaic cells are fixed to walls of the pipes exposed to the solar radiation and forming the exposure face of the bearing structure and wherein inner walls of the pipes form the heat transfer region.

17. The photovoltaic module of claim 16, wherein the pipes forming the bearing structure are arranged to form the channel that is substantially U-shaped in cross section.

18. The photovoltaic module of claim 16, wherein the pipes convey the heat-transfer fluid from a heat-transfer fluid transport inlet to a heat-transfer fluid transport outlet.

19. The photovoltaic module of claim 18, wherein the heat-transfer fluid transport inlet and the heat-transfer fluid transport outlet are configured to be interconnectable via a heat exchanger cooling the heat-transfer fluid passing through the bearing structure.

20. The photovoltaic module of claim 15, wherein the bearing structure is formed by:
a block of thermal conductive material comprising a non-planar exposure face forming a channel, the photovoltaic cells being fixed over walls of the channel, and a heat a heat transfer face forming an open cavity;
a plate made of a conductive material forming a cover for the cavity;
wherein the cavity comprising a plurality of longitudinal furrows, ends of the furrows opening onto two transverse furrows;
wherein the heat transfer face is configured, when the cavity is covered by the plate, such that the longitudinal and transverse furrows form separate pipes in which the heat-transfer fluid circulates, the longitudinal pipes communicating with two transverse pipes via their ends; and
wherein the cover is equipped with two diametrically opposed openings arranged to open out at opposite ends of the two transverse pipes.

21. The photovoltaic module of claim 20, wherein the transverse furrows are configured to form a distribution channel for distributing the heat-transfer fluid at an entry to the longitudinal pipes, and a collector for collecting the heat-transfer fluid at an exit from the longitudinal pipes; and wherein each transverse pipe having a section which varies continuously over their length, the openings for the entry and exit of the heat-transfer fluid being arranged so as to open onto larger ends of the transverse pipes.

22. The photovoltaic module of claim 20, wherein the cover comprises a connection element for connecting the photovoltaic module to an external system for circulating and conditioning the heat-transfer fluid.

23. The photovoltaic module of claim 20, wherein the bearing structure comprises U-shaped interior comprising a device for refracting and reflecting solar rays.

24. The photovoltaic module of claim 23, further comprising a passive optical device housed in an inner cavity of the channel, the passive optical device comprising two semi-transparent sheets arranged to form adjacent faces of a triangular prism, an edge of the triangular prism joining the two adjacent faces being directed toward the outside of the channel; and wherein the semi-reflective sheets being dimensioned to reflect some of the radiation received via the exposure face onto one of the walls of the channel.

25. A photovoltaic panel with a heat exchanger, comprising a plurality of photovoltaic modules with heat exchangers of claim 15, wherein the photovoltaic modules being juxtaposed with respect to one another, the bearing structures of the different modules being mechanically joined to form a common bearing structure comprising an exposure face forming a plurality of channels; wherein panels of the photovoltaic cells constituting the different modules are mounted over the walls of the channels; and further comprising a heat transfer surface covering all of the photovoltaic modules; and wherein the common bearing structure optimizes space occupied by the photovoltaic panel.

26. The photovoltaic panel of claim 25, further comprising a system for circulating the heat-transfer fluid and for conditioning the heat-transfer fluid, the system comprising a heat exchanger to cool the heat-transfer fluid passing through a cavity forming a heat exchange region of the photovoltaic panel.

27. The photovoltaic panel of claim 25, further comprising two additional photovoltaic panels fixed to outermost side walls of the common bearing structure and two reflectors, one of the reflectors being fixed to each of side edges of the common bearing structure; and wherein the reflectors are arranged to reflect the solar radiation onto the respective additional panels.

28. An overall energy production system, comprising photovoltaic panels of claim 25 and a device for utilizing heat produced in the heat exchanger to heat a body of water.
